(19) United States
(12) Patent Application Publication
(10) Pub. No.: US 2012/0126419 A1
(43) Pub. Date: May 24, 2012

(54) Substrate Arrangement and a Method of Manufacturing a Substrate Arrangement

(76) Inventors: Vaidyanathan Kripesh, Singapore (SG); Navas Khan Orattikalandar, Singapore (SG); Srinivasa Rao Vempati, Singapore (SG); Yak Long Samuel Lim, Singapore (SG); Yee Mong Khoo, Singapore (SG); Chee Houe Khong, Singapore (SG); Xiao Wu Zhang, Singapore (SG); Tai Chong Chai, Singapore (SG); Hon-Shing John Lau, Singapore (SG)

(21) Appl. No.: 13/055,525

(22) PCT Filed: Jul. 24, 2008
(86) PCT No.: PCT/SG2008/000268

§ 371 Date: Jun. 16, 2011

(51) Int. Cl. H01L 23/522; H01L 21/768

(52) U.S. Cl. 257/774; 438/667; 257/E23.145; 257/E21.597

(57) ABSTRACT

According to one embodiment of the present invention, a substrate arrangement is provided. The substrate arrangement includes a first substrate; a second substrate positioned above the first substrate, the second substrate comprising a first through hole; a third substrate positioned above the second substrate, the third substrate comprising a second through hole; a first electrically conductive interconnect pillar positioned on the first substrate and extending from the first substrate through the first through hole to electrically contact the third substrate; and a second electrically conductive interconnect pillar positioned on the second substrate and extending from the second substrate through the second through hole. A method of manufacturing a substrate arrangement is also provided.

### FIELD OF INVENTION

The present invention relates generally to a substrate arrangement and a method of manufacturing a substrate arrangement. The present invention also relates generally to a chip and a method of manufacturing a chip.

### BACKGROUND OF INVENTION

There is a need to reduce mounting area of electronic components so as to improve system performance and to reduce system size for example in mobile devices. One method to realize this is through a system-in-package (SiP) technology. The SiP technology involves stacking of dies on top of each other. The interconnection between the stacked dies may be achieved by a through silicon via (TSV) technology.

The key process technologies for 3-D die or chip stacking with TSV interconnects are namely, via formation, deposition of insulator, barrier and seed layers, copper plating and wafer thinning. In this regard, there are many challenges that may hinder this technology from being implemented in the large scale. These challenges include drilling of the vias, filling of the vias and thin wafer handling.

Using the via last approach, there are a few issues during the via etching and seed layer deposition and copper (Cu) filling. Cratering at the end of the via etching may prevent the seed layer from being deposited at the sides or bottom of the vias, thereby resulting in poor Cu filling and breaks the connection of the via which results in open circuit. Moreover pad delamination from the Cu filled vias surfaces occurs due to either contamination or stress.

Therefore, there is still a need for an improved structure and method to provide interconnection for stack chips or carrier.

### SUMMARY OF INVENTION

According to one embodiment of the present invention, a substrate arrangement is provided. The substrate arrangement includes a first substrate; a second substrate positioned above the first substrate, the second substrate comprising a first through hole; a third substrate positioned above the second substrate, the third substrate comprising a second through hole; a first electrically conductive interconnect pillar positioned on the first substrate and extending from the first substrate through the first through hole to electrically contact the third substrate; and a second electrically conductive interconnect pillar positioned on the second substrate and extending from the second substrate through the second through hole.

According to one embodiment of the present invention, a method of manufacturing a substrate arrangement is provided. The method includes forming a second substrate above a first substrate; forming a first through hole through the second substrate; forming a third substrate above the second substrate; forming a second through hole through the third substrate; forming a first electrically conductive interconnect pillar on the first substrate, the first electrically conductive interconnect pillar extending from the first substrate through the first through hole to electrically contact the third substrate; and forming a second electrically conductive interconnect pillar on the second substrate, the second electrically conductive interconnect pillar extending from the second substrate through the second through hole.

According to one embodiment of the present invention, a substrate arrangement is provided. The substrate arrangement includes a first substrate; a second substrate positioned above the first substrate, the second substrate comprising a first through hole; a third substrate positioned above the second substrate, the third substrate comprising a second through hole; a first electrically conductive interconnect pillar positioned on the first substrate and extending from the first substrate through the first through hole to electrically contact the third substrate; wherein the first through hole and the second through hole are aligned along a different axis perpendicular to a plane of the first substrate.

According to one embodiment of the present invention, a chip is provided. The chip includes a substrate having an electrical circuit formed therein; an electrically conductive interconnect pillar positioned on a first surface of the substrate and extending from the first surface of the substrate; and a through hole formed through the substrate, wherein the through hole is formed in such a dimension that an electrically conductive interconnect pillar of another substrate of substantially the same dimension as the electrically conductive interconnect pillar can be received in the through hole.

According to one embodiment of the present invention, a method of manufacturing a chip is provided. The method includes forming an electrical circuit in a substrate; forming an electrically conductive interconnect pillar on a first surface of the substrate, the electrically conductive interconnect pillar extending from the first surface of the substrate; forming a through hole through the substrate, wherein the through hole is formed in such a dimension that an electrically conductive interconnect pillar of another substrate of substantially the same dimension as the electrically conductive interconnect pillar can be received in the through hole.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a cross-sectional view of a substrate arrangement according to one embodiment of the present invention;

FIG. 2 shows a cross-sectional view of a substrate arrangement according to another embodiment of the present invention;

FIG. 3 shows a cross-sectional view of a substrate arrangement according to a further embodiment of the present invention;

FIG. 4A to 4D show a method of manufacturing a substrate arrangement according to one embodiment of the present invention;

FIG. 5A to 5E show a method of manufacturing a substrate arrangement according to another embodiment of the present invention;

FIG. 6A to 6B show a method of manufacturing a substrate arrangement according to a further embodiment of the present invention;

FIG. 7A to 7B show a method of manufacturing a substrate arrangement according to another further embodiment of the present invention;

FIG. 8A to 8B show a method of manufacturing a substrate arrangement according to yet a further embodiment of the present invention;

FIG. 9A to 9N show a method of manufacturing a chip according to one embodiment of the present invention;

FIG. 10A to 10N show a method of manufacturing a chip according to another embodiment of the present invention;

FIG. 11 shows an electrical model of a substrate arrangement according to one embodiment of the present invention;

FIG. 12 shows a comparison of simulation results of various embodiments of a substrate arrangement according to one embodiment of the present invention;

FIG. 13A to 13C show types of stresses on a substrate arrangement according to one embodiment of the present invention;

### DESCRIPTION

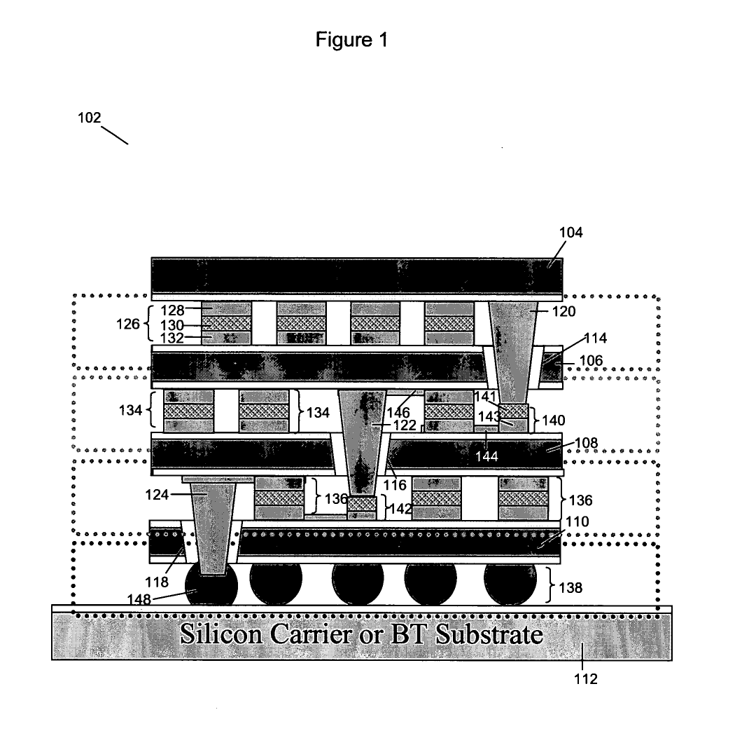

FIG. 1 shows a cross-sectional view of a substrate arrangement 102 according to one embodiment of the present invention. The substrate arrangement 102 includes a first substrate 104, a second substrate 106 positioned below the first substrate 104, a third substrate 108 positioned below the second substrate 106, a fourth substrate 110 positioned below the third substrate 108 and a fifth substrate 112 positioned below the fourth substrate 110. The second substrate 106 includes a first through hole 114, the third substrate 108 includes a second through hole 116 and the fourth substrate 110 includes a third through hole 118. A first electrically conductive interconnect pillar 120 is positioned on the first substrate 104 and extends from the first substrate 104 through the first through hole 114 to electrically contact the third substrate 108. A second electrically conductive interconnect pillar 122 is positioned on the second substrate 106 and extends from the second substrate 106 through the second through hole 116 to electrically contact the fourth substrate 110. A third electrically conductive interconnect pillar 124 is positioned on the third substrate 108 and extends from the third substrate 108 through the third through hole 118 to electrically contact the fifth substrate 112.

In one embodiment, the second substrate 106 is positioned below and in contact with the first substrate 104 via a plurality of first metallic interconnects 126. Each of the plurality of first metallic interconnects 126 may include a solder material or a three layer arrangement. The three layer arrangement may include a first metallic layer 128, a second metallic layer 130 arranged below the first metallic layer 128 and a third metallic layer 132 arranged below the second metallic layer 130. The first metallic layer 128 is in contact with the first substrate 104 and the third metallic layer 132 is in contact with second substrate 106. In FIG. 1, the first metallic layer 128 and the third metallic layer 132 may include a conductive material such as a copper (Cu) material and the second metallic layer 130 may also include a conductive material such as a tin (Sn) material, gold (Au), or a Gold-Tin (AuSN) solder alloy. In one embodiment, the first metallic layer 128 and the third metallic layer 132 is a copper pad.

In one embodiment, the third substrate 108 is positioned below and in contact with second substrate 106 via a plurality of second metallic interconnects 134. The fourth substrate 110 is positioned below and in contact with the third substrate 108 via a plurality of third metallic interconnects 136. In FIG. 1, each of the plurality of first metallic interconnects 126, each of the plurality of second metallic interconnects 134 and each of the plurality of third metallic interconnects 136 is the same.

In one embodiment, the fifth substrate 112 is positioned below and in contact with the fourth substrate 110 via a plurality of fourth metallic interconnects 138. In FIG. 1, each of the plurality of fourth metallic interconnects 138 includes a solder material. Each of the plurality of fourth metallic interconnects 138 may be a solder bump. In one embodiment, each of the plurality of fourth metallic interconnects 138 is any suitable conductive material.

In one embodiment, the first electrically conductive interconnect pillar 120 is arranged in contact with the third substrate 108 via a fifth metallic interconnect 140. The second electrically conductive interconnect pillar 122 is arranged in contact with the fourth substrate 110 via a sixth metallic interconnect 142. The fifth metallic interconnect 140 includes a fourth metallic layer 141 and a fifth metallic layer 143. The fourth metallic layer 141 is in contact with the first electrically conductive interconnect pillar 120 and the fifth metallic layer 143 is in contact with the third substrate 108. The fourth metallic layer 141 includes a tin material, gold (Au), or a Gold-Tin (AuSN) solder alloy and the fifth metallic layer 143 includes a copper material. In FIG. 1, the fifth metallic interconnect 140 is the same as the sixth metallic interconnect 142. In one embodiment, the fourth metallic layer 141 and the fifth metallic layer 143 are any suitable conductive materials.

In one embodiment, the fifth metallic layer 143 is in contact with one of the plurality of second metallic interconnects 134 via a first metallic connection 144 and the second electrically conductive interconnect pillar 122 is in contact with one of the plurality of second metallic interconnects 134 via a second metallic connection 146. In FIG. 1, the first metallic connection 144 and the second metallic connection 146 includes a copper material. In one embodiment, the first metallic connection 144 and the second metallic connection 146 are any suitable conductive materials.

In FIG. 1, the first electrically conductive interconnect pillar 120 includes a copper material. The first electrically conductive interconnect pillar 120 may be termed “a copper post” or “a copper column”. In FIG. 1, the first electrically conductive interconnect pillar 120, the second electrically interconnect pillar 122 and the third electrically conductive interconnect pillar 124 are the same. In one embodiment, the first electrically conductive interconnect pillar 120, the second electrically interconnect pillar 122 and the third electrically conductive interconnect pillar 124 include any suitable conductive material.

In FIG. 1, the first substrate 104 is a semiconductor substrate with an electrical circuit formed therein. In one embodiment, the first substrate 104 may also be a semiconductor chip, a logic chip or a memory chip. The first substrate 104, the second substrate 106, the third substrate 108 and the fourth substrate 110 may be the same.

In FIG. 1, the fifth substrate 112 is a semiconductor substrate. In one embodiment, the fifth substrate 112 may be a silicon carrier or a bismaleimide triazine (BT) substrate or ceramic substrate. The fifth substrate 112 serves as a support substrate for the subsequent stacking of the substrates.

In FIG. 1, the first through hole 114 and the second through hole 116 are aligned along a different axis perpendicular to a plane of the first substrate 104. The second through hole 116 and the third through hole 118 are aligned along a different axis perpendicular to a plane of the first substrate 104.

In one embodiment, the first substrate 104, the second substrate 106, the third substrate 108, the fourth substrate 110 and the fifth substrate 112 are arranged parallel to each other.

In one embodiment, the third electrically conductive interconnect pillar 124 is arranged in contact with the fifth substrate 112 via a seventh metallic interconnect 148. The seventh metallic interconnect 148 may be the same as one of the plurality of fourth metallic interconnects 138.

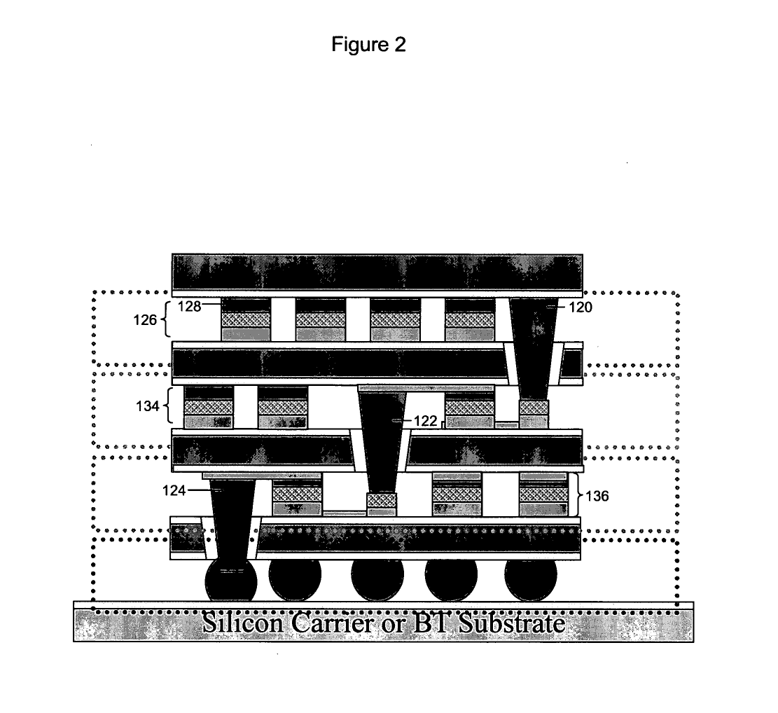

FIG. 2 shows a cross-sectional view of a substrate arrangement according to another embodiment of the present invention. FIG. 2 shows a similar substrate arrangement as FIG. 1 except that the first electrically conductive interconnect pillar 120, the second electrically interconnect pillar 122 and the third electrically conductive interconnect pillar 124 include a solder material instead of a copper material as earlier shown in FIG. 1. In addition, the first metallic layer 128 of each of the plurality of first metallic interconnects 126, of each of the plurality of second metallic interconnects 134 and of each of the plurality of third metallic interconnects 136 includes a solder material instead of a copper material as earlier shown in FIG. 1.

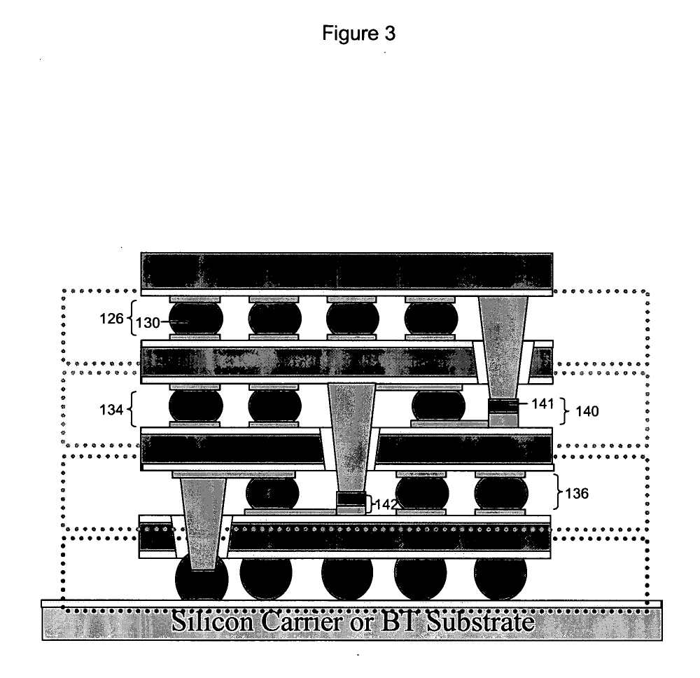

FIG. 3 shows a cross-sectional view of a substrate arrangement according to a further embodiment of the present invention. FIG. 3 shows a similar substrate arrangement to FIG. 1 except that the second metallic layer 130 of each of the plurality of first metallic interconnects 126, of each of the plurality of second metallic interconnects 134 and of each of the plurality of third metallic interconnects 136 includes a solder bump or solder ball material. The second metallic layer 130 in FIG. 3 may be a solder bump. In addition, the fourth metallic layer 141 of the fifth metallic interconnect 140 and the sixth metallic interconnect 142 includes a solder material instead of a Sn material.

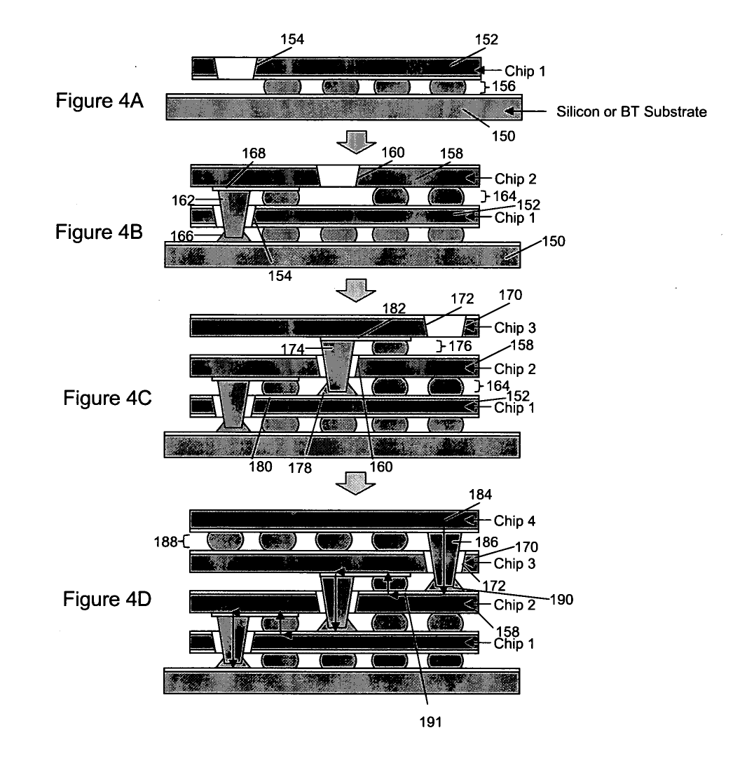

FIG. 4A to 4D show a method of manufacturing a substrate arrangement according to one embodiment of the present invention. FIG. 4A shows a substrate arrangement including a first substrate 150. A second substrate 152 is positioned above the first substrate 150, the second substrate 152 including a first through hole 154. The second substrate 152 is positioned above and in contact with the first substrate 150 via a plurality of first metallic interconnects 156. In one embodiment, each of the plurality of the first metallic interconnects 156 includes a solder material. The first substrate 150 includes a silicon or a BT substrate. The second substrate 152 includes a semiconductor substrate with an electrical circuit formed therein.

Next, FIG. 4B shows a stacking of a third substrate 158 above the second substrate 152. The third substrate 158 includes a second through hole 160. A first electrically conductive interconnect pillar 162 is positioned on the third substrate 158 and extends from the third substrate 158 through the first through hole 154 to electrically contact the first substrate 150. The third substrate 158 is positioned above and in contact with the second substrate 152 via a plurality of second metallic interconnects 164. The first electrically conductive interconnect pillar 162 is in contact with the first substrate 150 via a third metallic interconnect 166. The first electrically conductive interconnect pillar 162 is in contact with one of the plurality of the second metallic interconnects 164 via a first metallic connection 168. In one embodiment, the first electrically conductive interconnect pillar 162 includes a copper material or a solder material. Each of the plurality of second metallic interconnects 164 and the third metallic interconnect 166 includes a solder material or a stacked layer arrangement as mentioned in FIG. 1, 2 or 3. The first metallic connection 168 includes a copper material. The third substrate 158 includes a semiconductor substrate with an electrical circuit formed therein.

Further, FIG. 4C shows a stacking of a fourth substrate 170 above the third substrate 158. The fourth substrate 170 includes a third through hole 172. A second electrically conductive interconnect pillar 174 is positioned on the fourth substrate 170 and extends from the fourth substrate 170 through the second through hole 160 to electrically contact the second substrate 152. The fourth substrate 170 is positioned above and in contact with the third substrate 158 via a fourth metallic interconnect 176. The second electrically conductive interconnect pillar 174 is in contact with the second substrate 152 via a fifth metallic interconnect 178. The fifth metallic interconnect 178 is in contact with each of the plurality of second metallic interconnects 164 via a second metallic connection 180 and the second electrically conductive interconnect pillar 174 is in contact with the fourth metallic interconnect 176 via a third metallic connection 182. In one embodiment, the second electrically conductive interconnect pillar 174 includes a copper material or a solder material. The fourth metallic interconnect 176 and the fifth metallic interconnect 178 include a solder material or a stacked layer arrangement as mentioned in FIG. 1, 2 or 3. The second metallic connection 180 and the third metallic connection 182 include a copper material. The fourth substrate 170 includes a semiconductor substrate with an electrical circuit formed therein.

Then, FIG. 4D shows a stacking of a fifth substrate 184 above the fourth substrate 170. A third electrically conductive interconnect pillar 186 is positioned on the fifth substrate 184 and extends from the fifth substrate 184 through the third through hole 172 to electrically contact the third substrate 158. The fifth substrate 184 is positioned above and in contact with the fourth substrate 170 via a plurality of sixth metallic interconnects 188. The third electrically conductive interconnect pillar 186 is in contact with the third substrate 158 via a seventh metallic interconnect 190. The seventh metallic interconnect 190 is in contact with the fourth metallic interconnect 176 via a fourth metallic connection 191. In one embodiment, the third electrically conductive interconnect pillar 186 includes a copper material or a solder material. Each of the plurality of sixth metallic interconnects 188 and the seventh metallic interconnect 190 include a solder material or a stacked layer arrangement as mentioned in FIG. 1, 2 or 3. The fourth metallic connection 191 include a copper material. The fifth substrate 184 includes a semiconductor substrate with an electrical circuit formed therein.

In one embodiment, the second substrate 152, the third substrate 158, the fourth substrate 170 and the fifth substrate 184 are the same. In one embodiment, more substrates may be stacked depending on requirements. The first electrically conductive interconnect pillar 162, the second electrically conductive interconnect pillar 174 and the third electrically conductive interconnect pillar 186 are the same. Each of the plurality of first metallic interconnects 156, each of the plurality of second metallic interconnects 164, the third metallic interconnect 166, the fourth metallic interconnect 176, the fifth metallic interconnect 178, each of the plurality of sixth metallic interconnects 188 and the seventh metallic interconnect 190 are the same. The first metallic connection 168, the second metallic connection 180, the third metallic connection 182 and the fourth metallic connection 191 are the same. The connection between the respective substrates as as shown by the arrows.

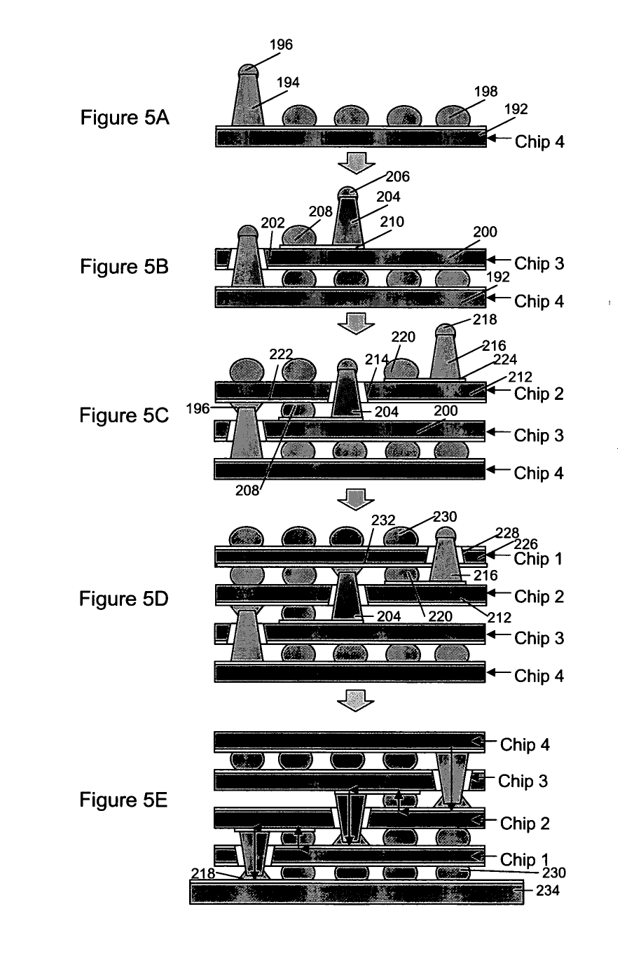

FIG. 5A to 5E show a method of manufacturing a substrate arrangement according to another embodiment of the present invention. FIG. 5A to 5E shows that a plurality of substrates, each of which with an electrical circuit formed therein, being stacked together first before being placed on a silicon carrier or a BT substrate or a ceramic substrate.

FIG. 5A shows a substrate arrangement including a first substrate 192. A first electrically conductive interconnect pillar 194 is positioned on the first substrate 192 and extends from a surface of the first substrate 192. A first metallic interconnect 196 is formed on a top surface of the first electrically conductive interconnect pillar 194. A plurality of second metallic interconnects 198 are formed on the same surface of the first substrate 192. In one embodiment, the first substrate 192 includes a semiconductor substrate with an electrical circuit formed therein. The first electrically conductive interconnect pillar 194 includes a copper material or a solder material. The first metallic interconnect 196 and each of the plurality of second metallic interconnects 198 includes a solder material or a stacked arrangement as mentioned in FIG. 1, 2 or 3.

Next, FIG. 5B shows a stacking of a second substrate 200 above the first substrate 192. The second substrate 192 includes a first through hole 202. The second substrate 200 is stacked above the first substrate 192 such that the first electrically conductive interconnect pillar 194 can be received in the first through hole 202. A second electrically conductive interconnect pillar 204 is positioned on the second substrate 200 and extends from a surface of the second substrate 200. A third metallic interconnect 206 is formed on a top surface of the second electrically conductive interconnect pillar 204. A fourth metallic interconnect 208 is also formed on the same surface of the second substrate 200. The second electrically conductive interconnect pillar 204 is in contact with the fourth metallic interconnect 208 via a first metallic connection 210. In one embodiment, the second substrate 200 includes a semiconductor substrate with an electrical circuit formed therein. The second electrically conductive interconnect pillar 204 includes a copper material or a solder material. The third metallic interconnect 206 and the fourth metallic interconnect 208 includes a solder material or a stacked arrangement as mentioned in FIG. 1, 2 or 3. The first metallic connection 210 includes a copper material.

Further, FIG. 5C shows a stacking of a third substrate 212 above the second substrate 200. The third substrate 212 includes a second through hole 214. The third substrate 212 is stacked above the second substrate 200 such that the second electrically conductive interconnect pillar 204 can be received in the second through hole 214. A third electrically conductive interconnect pillar 216 is positioned on the third substrate 212 and extends from a surface of the third substrate 212. A fifth metallic interconnect 218 is formed on a top surface of the third electrically conductive interconnect pillar 216. A plurality of sixth metallic interconnects 220 are also formed on the same surface of the second substrate 200. The first metallic interconnect 196 is in contact with the fourth metallic interconnect 208 via a second metallic connection 222. The third electrically conductive interconnect pillar 216 is in contact with one of the plurality of sixth metallic interconnects 220 via a third metallic connection 224. In one embodiment, the third substrate 212 includes a semiconductor substrate with an electrical circuit formed therein. The third electrically conductive interconnect pillar 216 includes a copper material or a solder material. The fifth metallic interconnect 218 and the at least one sixth metallic interconnect 220 includes a solder material or a stacked arrangement as mentioned in FIG. 1, 2 or 3. The second metallic connection 222 and the third metallic connection 224 includes a copper material.

Then, FIG. 5D shows a stacking of a fourth substrate 226 above the third substrate 212. The fourth substrate 226 includes a third through hole 228. The fourth substrate 226 is stacked above the third substrate 212 such that the third electrically conductive interconnect pillar 216 can be received in the third through hole 228. A plurality of seventh metallic interconnects 230 are formed on a surface of the fourth substrate 226. The second electrically conductive interconnect pillar 204 is in contact with one of the plurality of sixth metallic interconnects 220 via a fourth metallic connection 232. In one embodiment, the fourth substrate 226 includes a semiconductor substrate with an electrical circuit formed therein. Each of the seventh metallic interconnects 230 includes a solder material or a stacked arrangement as mentioned in FIG. 1, 2 or 3. The fourth metallic connection 232 includes a copper material.

Then, FIG. 5E shows a rotation of the substrate arrangement as formed in FIG. 5D such that each of the plurality of seventh metallic interconnects 230 is in contact with a fifth substrate 234. The fifth metallic interconnect 218 is in contact with the fifth substrate 234. In one embodiment, the fifth substrate 234 includes a silicon or a BT substrate or a ceramic substrate.

In one embodiment, the first substrate 192, the second substrate 200, the third substrate 212 and the fourth substrate 226 are the same. The first electrically conductive interconnect pillar 194, the second electrically conductive interconnect pillar 204 and the third electrically conductive interconnect pillar 216 are the same. The first metallic interconnect 196, each of the plurality of second metallic interconnects 198, the third metallic interconnect 206, the fourth metallic interconnect 208, the fifth metallic interconnect 218, each of the plurality of sixth metallic interconnects 220 and each of the plurality of seventh metallic interconnects 230 are the same. The first metallic connection 210, the second metallic connection 222, the third metallic connection 224 and the fourth metallic connection 232 are the same. The connection between the respective substrates as as shown by the arrows.

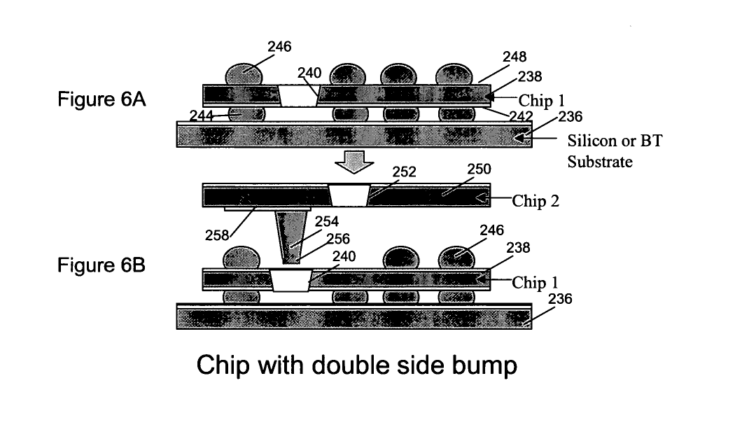

FIG. 6A to 6B show a method of manufacturing a substrate arrangement according to a further embodiment of the present invention. FIG. 6A shows a substrate arrangement including a first substrate 236. A second substrate 238 is positioned above the first substrate 236, the second substrate 238 including a first through hole 240. A first surface 242 of the second substrate 238 is in contact with the first substrate 236 via a plurality of first metallic interconnects 244. A plurality of second metallic interconnects 246 are positioned on a second surface 248 of the second substrate 238. The first surface 242 of the second substrate 238 is positioned opposite the second surface 248 of the second substrate 238. In this regard, FIG. 6A shows the second substrate 238 including a double side solder bump. In one embodiment, one of the plurality of first metallic interconnects 244 and one of a plurality of second metallic interconnects 246 includes a solder material or a solder bump. The first substrate 236 includes a silicon or a BT substrate. The second substrate 238 includes a semiconductor substrate with an electrical circuit formed therein.

Next, FIG. 6B shows a stacking of a third substrate 250 above the second substrate 238. The third substrate 250 includes a second through hole 252. A first electrically conductive interconnect pillar 254 is positioned on the third substrate 250 and extends from the third substrate 250 through the first through hole 240 to electrically contact the first substrate 236. The third substrate 250 is positioned above and in contact with the second substrate 238 via each of the plurality of second metallic interconnects 246. The first electrically conductive interconnect pillar 254 is in contact with the first substrate 236 via a third metallic interconnect 256. The first electrically conductive interconnect pillar 254 is in contact with one of the plurality of second metallic interconnects 246 via a first metallic connection 258. In one embodiment, the first electrically conductive interconnect pillar 254 includes a copper material or a solder material. The third metallic interconnect 256 includes a solder material or a stacked layer arrangement as mentioned in FIG. 1, 2 or 3. The first metallic connection 258 includes a copper material. The third substrate 250 includes a semiconductor substrate with an electrical circuit formed therein.

In one embodiment, the second substrate 238 and the third substrate 250 are the same. Each of the plurality of first metallic interconnects 244, each of the plurality of second metallic interconnect 246 and the third metallic interconnect 256 are the same.

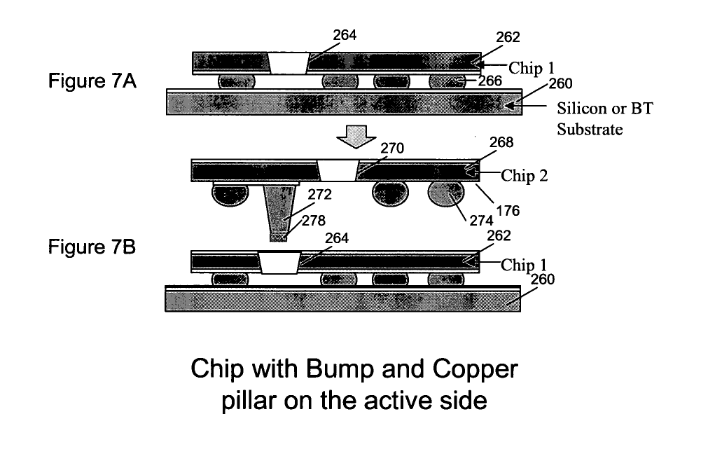

FIG. 7A to 7B show a method of manufacturing a substrate arrangement according to another further embodiment of the present invention.

FIG. 7A shows a substrate arrangement including a first substrate 260. A second substrate 262 is positioned above the first substrate 260, the second substrate 262 including a first through hole 264. The second substrate 262 is positioned above and in contact with the first substrate 260 via a plurality of first metallic interconnects 266. In one embodiment, each of the plurality of first metallic interconnects 266 includes a solder material. The first substrate 260 includes a silicon or a BT substrate. The second substrate 262 includes a semiconductor substrate with an electrical circuit formed therein.

Next, FIG. 7B shows a stacking of a third substrate 268 above the second substrate 262. The third substrate 268 includes a second through hole 270. A first electrically conductive interconnect pillar 272 is positioned on the third substrate 268 and extends from a first surface 176 of the third substrate through the first through hole 264 to electrically contact the first substrate 260. The third substrate 268 is positioned above the second substrate 262 and the first surface 276 of the third substrate 268 is in contact with the second substrate 262 via a plurality of second metallic interconnects 274. The first surface 276 may be considered as the active side of the third substrate 268. In this regard, the first electrically conductive interconnect pillar 272 and each of the plurality of second metallic interconnects 274 are positioned on the active side of the third substrate 268. The first electrically conductive interconnect pillar 272 is in contact with the first substrate 260 via a third metallic interconnect 278. The first electrically conductive interconnect pillar 272 is in contact with one of the plurality of second metallic interconnects 274 via a first metallic connection 280. In one embodiment, the first electrically conductive interconnect pillar 272 includes a copper material or a solder material. Each of the plurality of second metallic interconnects 274 and the third metallic interconnect 278 includes a solder material or a stacked layer arrangement as mentioned in FIG. 1, 2 or 3. The first metallic connection 280 includes a copper material. The third substrate 268 includes a semiconductor substrate with an electrical circuit formed therein.

In one embodiment, the second substrate 262 and the third substrate 268 are the same. Each of the plurality of first metallic interconnects 266, each of the plurality of second metallic interconnects 274 and the third metallic interconnect 278 are the same.

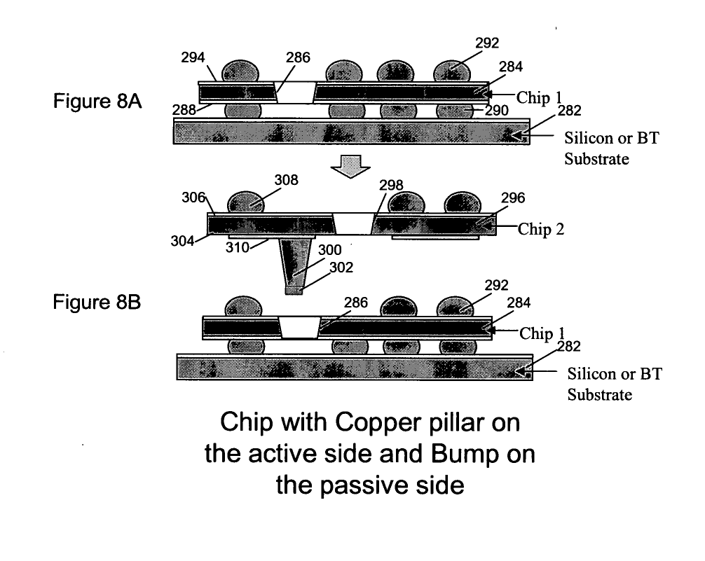

FIG. 8A to 8B show a method of manufacturing a substrate arrangement according to yet a further embodiment of the present invention. FIG. 8A shows a substrate arrangement including a first substrate 282. A second substrate 284 is positioned above the first substrate 282, the second substrate 284 including a first through hole 286. A first surface 288 of the second substrate 284 is in contact with the first substrate 282 via a plurality of first metallic interconnects 290. A plurality of second metallic interconnects 292 are positioned on a second surface 294 of the second substrate 284. The first surface 288 of the second substrate 284 is positioned opposite the second surface 294 of the second substrate 284. In one embodiment, each of the plurality of first metallic interconnects 290 and each of the plurality of second metallic interconnects 292 includes a solder material. The first substrate 282 includes a silicon or a BT substrate. The second substrate 284 includes a semiconductor substrate with an electrical circuit formed therein.

Next, FIG. 8B shows a stacking of a third substrate 296 above the second substrate 284. The third substrate 296 includes a second through hole 298. A first electrically conductive interconnect pillar 300 is positioned on the third substrate 296 and extends from a first surface 304 of the third substrate 296 through the first through hole 286 to electrically contact the first substrate 282. The third substrate 296 is positioned above and in contact with the second substrate 284 via each of the plurality of second metallic interconnects 292. The first electrically conductive interconnect pillar 300 is in contact with the first substrate 282 via a third metallic interconnect 302. A plurality of fourth metallic interconnect 308 are positioned on a second surface 306 of the third substrate 296 opposite to the first surface 304 of the third substrate 296. The first surface 304 of the third substrate 296 may be considered the active side of the substrate and the second surface 306 of the third substrate 296 may be considered the passive side of the substrate. In this regard, the first electrically conductive interconnect pillar 300 is positioned on the active side of the third substrate 296 and each of a plurality of fourth metallic interconnects 308 is positioned on the passive side of the third substrate 296. The first electrically conductive interconnect pillar 300 is in contact with each of the plurality of second metallic interconnects 292 via a first metallic connection 310. In one embodiment, the first electrically conductive interconnect pillar 300 includes a copper material or a solder material. The third metallic interconnect 302 and each of the plurality of fourth metallic interconnects 308 includes a solder material or a stacked layer arrangement as mentioned in FIG. 1, 2 or 3. The first metallic connection 310 includes a copper material. The third substrate 296 includes a semiconductor substrate with an electrical circuit formed therein.

In one embodiment, the second substrate 284 and the third substrate 296 are the same. Each of the plurality of first metallic interconnects 290, each of the plurality of second metallic interconnects 292, the third metallic interconnect 302 and each of the plurality of fourth metallic interconnects 308 is the same.

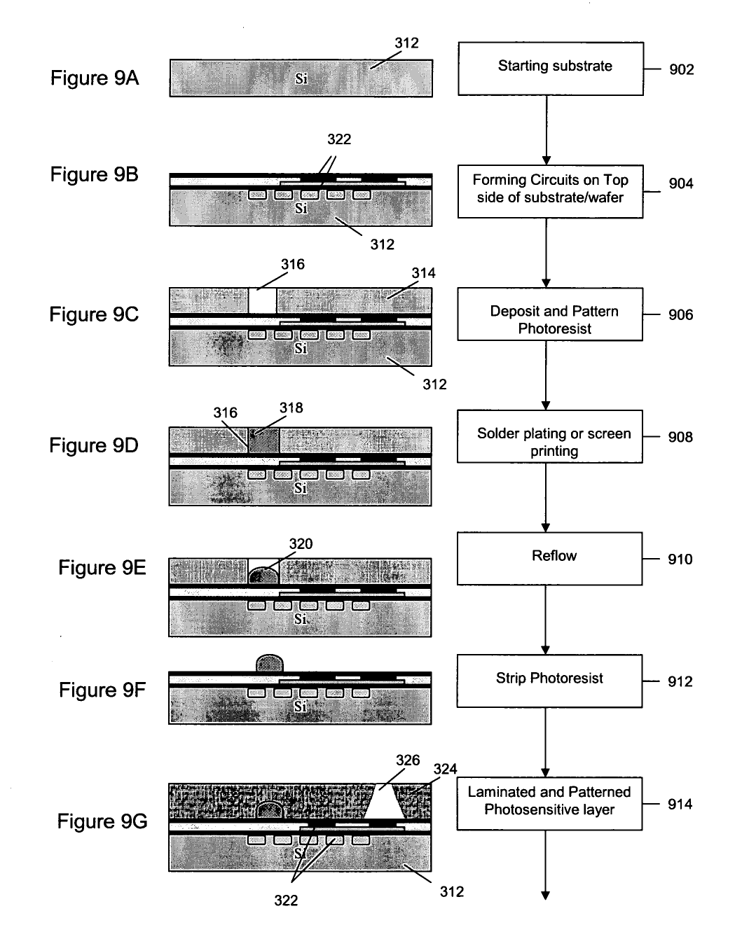

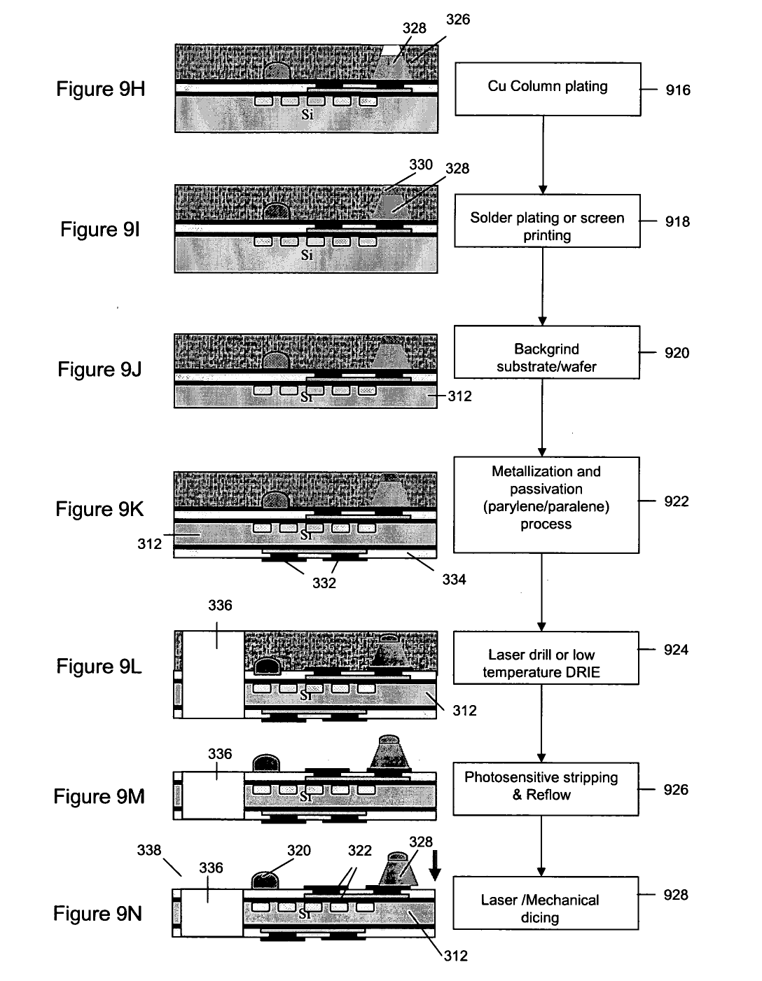

FIG. 9A to 9N show a method of manufacturing a chip according to one embodiment of the present invention. FIG. 9A shows a starting substrate 312. The substrate 312 may include a semiconductor material, for example, silicon (Si), silicon germanium (SiGe), Gallium arsenide (GaAs). (See block 902 in FIG. 9A.)

Next in FIG. 9B, circuits 322 are formed on a top side of the substrate 312 by an integrated circuit fabrication process. (See block 904 in FIG. 9B.)

In FIG. 9C, a photoresist (PR) layer 314 is applied or coated onto a top surface of the substrate 312. The photoresist layer 314 is then patterned to form an opening 316 thereby exposing a portion of the substrate 312 by standard photolithography techniques. (See block 906 in FIG. 9C.)

In FIG. 9D, a layer of solder material 318 is being deposited into the opening 316. The deposition of the layer of solder 318 may be carried out by a solder plating process or a screen printing process. (See block 908 in FIG. 9D.)

In FIG. 9E, the layer of solder 318 is reflowed to form a metallic interconnect 320. Solder reflow condition may vary depending on the type of solder material. The temperature for the solder reflow condition may range from about 100° C. to about 260° C. (See block 910 in FIG. 9E.)

In FIG. 9F, the photoresist layer 314 is removed or stripped away by a photoresist stripper (PRS). Photoresist stripping, or simply ‘resist stripping’, is the removal of unwanted photoresist layer from the substrate. In this regard, any other suitable techniques or processes may also be used in order to provide greater flexibility with respect to forming the metallic interconnect. (See block 912 in FIG. 9F.)

In FIG. 9G, a photosensitive layer 324 is applied to the surface of the substrate 312 where the circuits 322 are formed. The photosensitive layer 324 may include a material that experiences a change in its physical properties when exposed to a radiation source. In one embodiment, the photosensitive layer 324 includes a thick photoresist and any commercially available dry film. Examples of dry film include Ashai Sunfort dry film, Dupont dry film, JSR dry film, Nichgo ALPHO dry film. The average thickness of the photosensitive layer 324 is typically between about 10 to about 100 μm or about 10 to about 200 μm. For example, if a thickness of 200 μm is required, a double lamination or coating can be carried out. The photosensitive layer 324 is patterned so as to expose an area of the substrate 312 to form an opening 326 in the photosensitive layer 324. (See block 914 in FIG. 9G.)

In FIG. 9H, a portion of the opening 326 is subsequently filled with copper to form a electrically conductive interconnect pillar 328 by a process termed copper column plating or electroplating. Electroplating is the process by which a metal in its ionic form is supplied with electrons to form a non-ionic coating on a desired substrate. The most common system involves a chemical solution which contains the ionic form of the metal, an anode (positively charged) which may consist of the metal being plated (a soluble anode) or an insoluble anode (usually carbon, platinum, titanium, lead, or steel), and finally, a cathode (negatively charged) where electrons are supplied to produce a film of non-ionic metal. (See block 916 in FIG. 9H.)

In FIG. 9I, a layer of solder 330 is formed or deposited on the top surface of the electrically conductive interconnect pillar 328 by a process for example solder plating or solder paste printing. (See block 918 in FIG. 9I.)

In one embodiment, the electrically conductive interconnect pillar 328 may include any other suitable conductive materials. In this regard, the steps in FIG. 9H and FIG. 9I can be a single process step.

In FIG. 9J, the backside of the substrate 312 or device wafer is being thinned or backgrind to reduce the thickness of the substrate 312. The thinning or backgrinding is achieved by a mechanical, chemical, plasma process. (See block 920 in FIG. 9J.)

In FIG. 9K, a metal layer 332 and a passivation layer 334 are being deposited on the backside of the substrate 312 by a Electron Beam Evaporator, Physical vapor deposition, Chemical vapor deposition for example. (See block 922 in FIG. 9K.)

In FIG. 9L, a through hole 336 is formed through the substrate 312 by a laser drilling process or a deep reactive ion etching (DRIE). The through hole 336 is formed in such a dimension that an electrically conductive interconnect pillar of another substrate or die of the same dimension or of a different dimension as the electrically conductive interconnect pillar 328 formed in FIG. 9H can be received in the through hole 336. (See block 924 in FIG. 9L.)

In FIG. 9M, the photosensitive layer 324 is stripped. Stripping is the removal of the photosensitive layer 324 from the substrate 312, and involves immersing the structure containing the photosensitive layer 324 in a heated solution of sodium hydroxide (stripper solution) (or commonly known as caustic soda, lye, or sodium hydrate) and agitating the sodium hydroxide until the photosensitive layer 324 lifts off from the substrate 312. The photosensitive layer 324 can also be stripped by plasma ashing or with a PR stripper or an alkali containing solution such as sodium hydroxide. The sodium hydroxide has a typical concentration of about 1 to 10 wt %. (See block 926 in FIG. 9M.)

In FIG. 9N, the substrate 312 is diced or singulated to obtain individual chips 338 by a laser dicing process. The point of dicing is as shown by the arrow.

FIG. 9N shows a chip 338 including a substrate 312 having an electrical circuit 322 formed therein, an electrically conductive interconnect pillar 328 positioned on a first surface of the substrate 312 and extending from the first surface of the substrate 312 and a through hole 336 formed through the substrate 312, wherein the through hole 336 is formed in such a dimension that an electrically conductive interconnect pillar 328 of another substrate or die of the same dimension or of a different dimension as the electrically conductive interconnect pillar 328 can be received in the through hole 336. Further, a first metallic interconnect 320 is positioned on the first surface of the substrate 312, adjacent to the electrically conductive interconnect pillar 328. (See block 928 in FIG. 9N.)

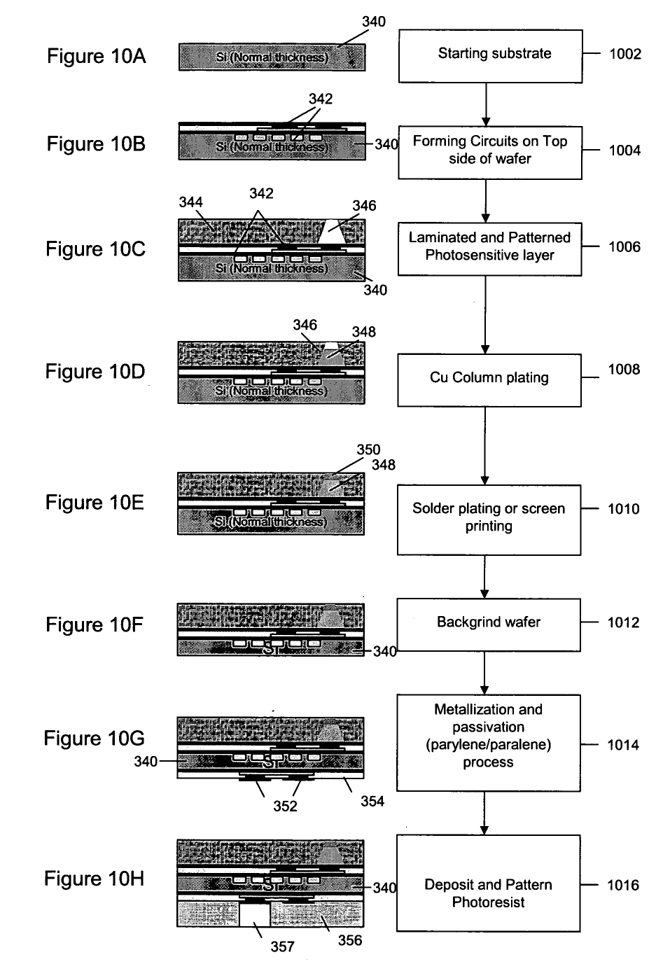

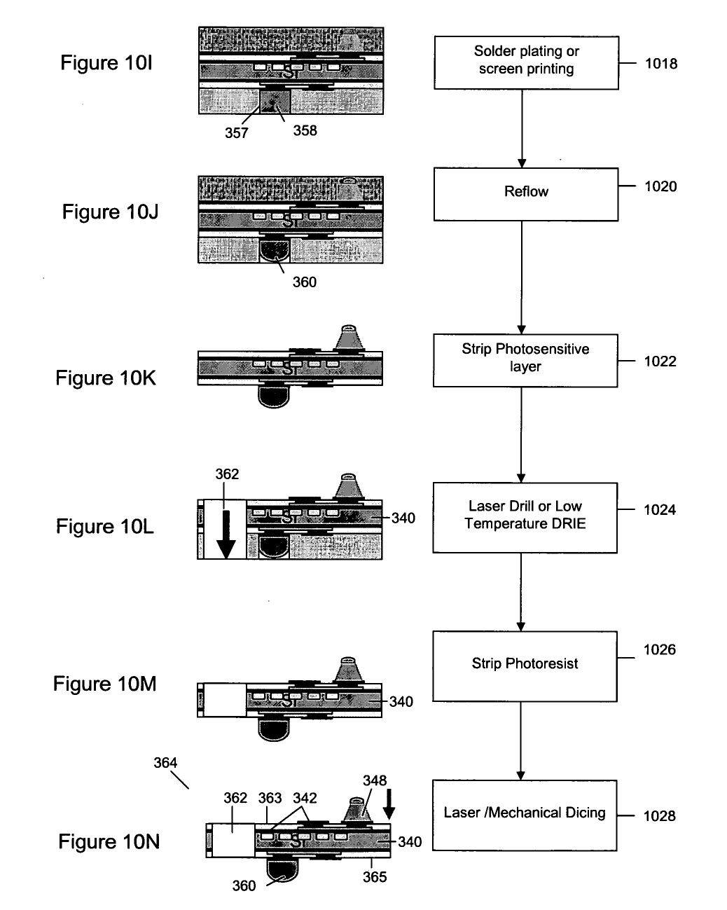

FIG. 10A to 10N show a method of manufacturing a chip according to another embodiment of the present invention. FIG. 10A shows a starting substrate 340. The substrate 340 may include a semiconductor material, for example, silicon (Si), Silicon germanium (SiGe), Gallium arsenide (GaAs). (See block 1002 in FIG. 10A.)

In FIG. 10B, circuits 342 are formed on a top side of the substrate 340 by an integrated circuit fabrication process (See block 1004 in FIG. 10B.)

In FIG. 10C, a layer of photosensitive layer 344 is applied to the surface of the substrate 340 where the circuits 342 are formed. The photosensitive layer 344 may include a material that experiences a change in its physical properties when exposed to a radiation source. In one embodiment, the photosensitive layer 344 includes a thick photoresist and any commercially available dry film. Examples of dry film include Ashai Sunfort dry film, Dupont dry film, JSR dry film, Nichgo ALPHO dry film. The average thickness of the photosensitive layer 344 is typically between about 10 to about 100 μm or about 10 to about 200 μm. For example, if a thickness of 200 μm is required, a double lamination can be carried out. The photosensitive layer 344 is patterned so as to expose an area of the substrate 340 to form an opening 346 in the photosensitive layer 344. (See block 1006 in FIG. 10C.)

In FIG. 10D, a portion of the opening 346 is subsequently filled with copper to form a electrically conductive interconnect pillar 348 by a process termed copper column plating or electroplating. Electroplating is the process by which a metal in its ionic form is supplied with electrons to form a non-ionic coating on a desired substrate. The most common system involves a chemical solution which contains the ionic form of the metal, an anode (positively charged) which may consist of the metal being plated (a soluble anode) or an insoluble anode (usually carbon, platinum, titanium, lead, or steel), and finally, a cathode (negatively charged) where electrons are supplied to produce a film of non-ionic metal. (See block 1008 in FIG. 10D.)

In FIG. 10E, a layer of solder 350 is formed or deposited on the top surface of the electrically conductive inteconnect pillar 348 by a process for example solder plating or solder paste printing. (See block 1010 in FIG. 10E.)

In one embodiment, the electrically conductive interconnect pillar 348 may include any other suitable conductive materials. In this regard, the steps in FIG. 10D and FIG. 10E can be a single process step.

In FIG. 10F, the backside of the substrate 340 or device wafer is being thinned or backgrind to reduce the thickness of the substrate 340. The thinning or backgrinding is achieved by a mechanical, chemical, plasma process. (See block 1012 in FIG. 10F.)

In FIG. 10G, a metal layer 352 and a passivation layer 354 are being deposited on the backside of the substrate 340 by a Electron Beam Evaporator, physical vapor deposition or chemical vapor deposition. (See block 1014 in FIG. 10G.)

In FIG. 10H, a photoresist (PR) layer 356 is applied or coated onto a top surface of the substrate 340. The photoresist layer 356 is then patterned to form an opening 357 thereby exposing a portion of the substrate 340 by standard photolithography techniques. (See block 1016 in FIG. 10H.)

In FIG. 10I, a layer of solder material 358 is being deposited into the opening 357. The deposition of the layer of solder 358 may be carried out by a solder plating process or a screen printing process. (See block 1018 in FIG. 10I.)

In FIG. 10J, the layer of solder 358 is reflowed to form a metallic interconnect 360. As mentioned earlier, solder reflow condition may vary depending on the type of solder material. The temperature for the solder reflow condition may range from about 100° C. to about 260° C. (See block 1020 in FIG. 10J.)

In FIG. 10K, the photosensitive layer 344 is stripped. Stripping is the removal of the photosensitive layer 344 from the substrate 340, and involves immersing the structure containing the photosensitive layer 344 in a heated solution of sodium hydroxide (stripper solution) (or commonly known as caustic soda, lye, or sodium hydrate) and agitating the sodium hydroxide until the photosensitive layer 344 lifts off from the substrate 340. The photosensitive layer 344 can be stripped with an alkali containing solution such as sodium hydroxide. The sodium hydroxide has a typical concentration of 1 to 10 wt %.(See block 1022 in FIG. 10K.)

In FIG. 10L, a through hole 362 is formed through the substrate 340 by a laser drilling process or a deep reactive ion etching (DRIE). The through hole 362 is formed in such a dimension that an electrically conductive interconnect pillar of another substrate or die of the same dimension or of a different dimension as the electrically conductive interconnect pillar 348 formed in FIG. 9H can be received in the through hole 362. (See block 1024 in FIG. 10L.)

In FIG. 10M, the photoresist layer 356 is removed or stripped away by a photoresist stripper (PRS). Photoresist stripping, or simply ‘resist stripping’, is the removal of unwanted photoresist layer from the substrate. Its objective is to eliminate the photoresist material from the substrate as quickly as possible, without allowing any surface materials under the photoresist to be attacked by the chemicals used. In this regard, any other suitable techniques or processes may also be used in order to provide greater flexibility with respect to forming the metallic interconnect. (See block 1026 in FIG. 10M.)

In FIG. 10N, the substrate 340 is diced or singulated to obtain individual chips 364 by a laser dicing process. The point of dicing is as shown by the arrow.

FIG. 10N shows a chip 364 including a substrate 340 having an electrical circuit 342 formed therein, an electrically conductive interconnect pillar 348 positioned on a first surface of the substrate 340 and extending from the first surface 363 of the substrate 340 and a through hole 362 formed through the substrate 340, wherein the through hole 362 is formed in such a dimension that an electrically conductive interconnect pillar of another substrate or die of the same dimension or of a different dimension as the electrically conductive interconnect pillar 348 can be received in the through hole 362. Further, a first metallic interconnect 360 is positioned on a second surface 365 of the substrate 340, adjacent to the electrically conductive interconnect pillar 348. The first surface 363 is opposite to the second surface 365 of the substrate 340. (See block 1028 in FIG. 10N.)

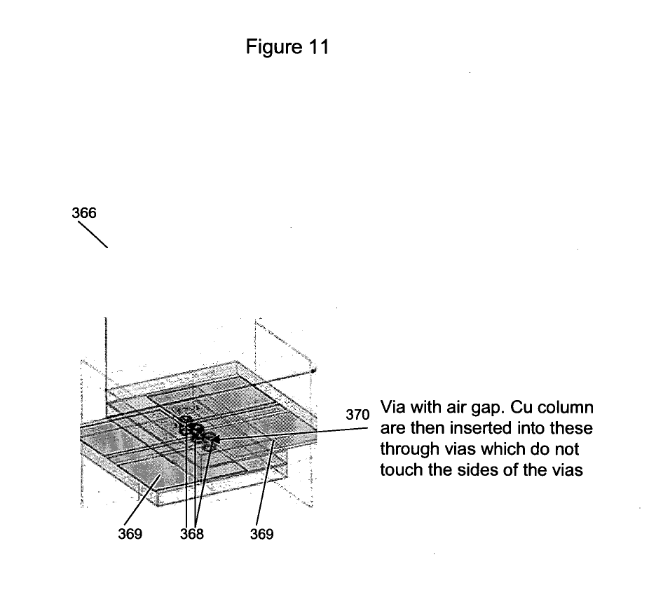

FIG. 11 shows an electrical model 366 of a substrate arrangement according to one embodiment of the present invention. FIG. 11 shows a plurality of electrically conductive interconnect pillars 368, isolated from the respective substrates 369 by respective air-gaps 370. The airgap 370 around the electrically conductive pillar provide a good signal or power isolation from the substrate 369.

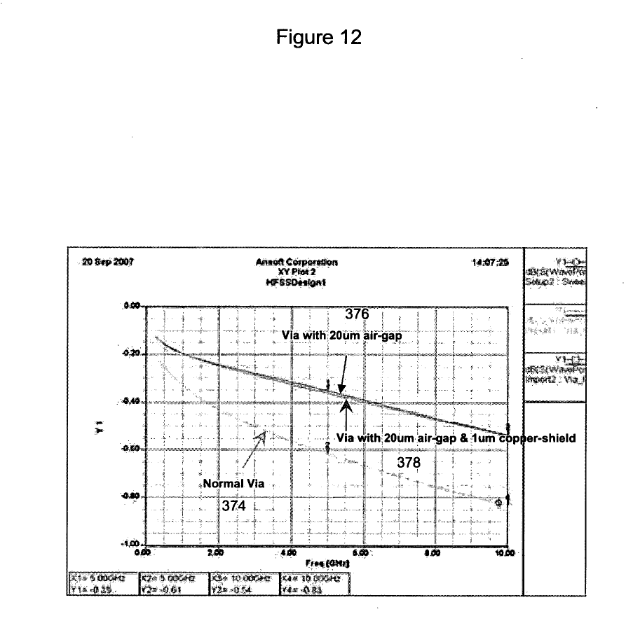

FIG. 12 shows a comparison of simulation results of various embodiments of a substrate arrangement according to one embodiment of the present invention. FIG. 12 shows a plot of signal insertion loss versus frequency. Plot 374 is for a normal via, plot 376 is for a through-hole or via with 20 μm air-gap and plot 378 is for a through hole or via with 20 μm air-gap and 1 μm copper-shield. The air gap around the electrically conductive pillar provides a smaller insertion loss at different signal transmission frequency.

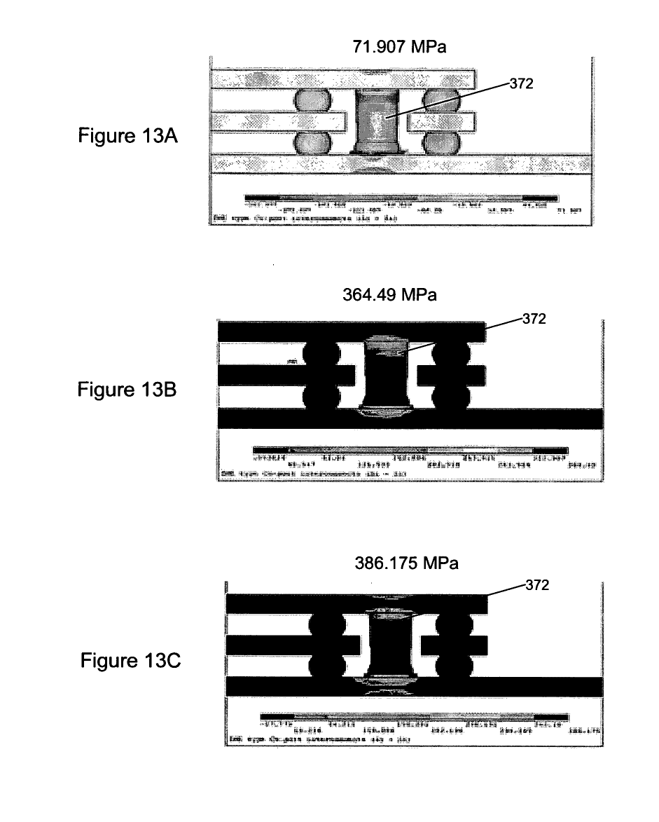

FIG. 13A to 13C show types of stresses on an electrically conductive interconnect pillar 372 of a substrate arrangement according to one embodiment of the present invention. FIG. 13A shows a normal stress on the electrically conductive interconnect pillar 372. The normal stress is about 71.907 MPa.

FIG. 13B shows a von-mises stress on the electrically conductive interconnect pillar 372 of a substrate arrangement. The von-mises stress or equivalent stress is about 364.49 MPa.

FIG. 13C shows a first principal stress on the electrically conductive interconnect pillar 372 of a substrate arrangement. The first principal stress or maximum stress in a principle plane is about 386.175 MPa.

In the following description, further aspects of embodiments of the present invention will be explained.

According to one embodiment of the present invention, a new design to improve the process, electrical and mechanical performances of current through silicon via (TSV) issues is proposed. Issue of via plating is eliminated by removing the need to plate the vias and replacing with conventional and established Cu columns. This method also allows the vias to be fully etched or drilled which eliminates cratering issues. With the new structure, modeling shows that there are improvements in the electrical and mechanical performances. The processes of how to fabricate the chip using low temperature processes are also shown.

According to one embodiment of the present invention, the substrates are stacked by a flipchip approach.

According to one embodiment of the present invention, the electrically conductive interconnect pillar is not in contact with the sides of the through hole formed in the substrate. This gives rise to respective air gaps between the electrically conductive interconnect pillar and the substrate which results in better electrical performance.

According to one embodiment of the present invention, stress locations are only located on the electrically conductive interconnect pillar.

According to one embodiment of the present invention, the second substrate is positioned above and in contact with the first substrate via at least one first metallic interconnect.

According to one embodiment of the present invention, the at least one first metallic interconnect includes a solder material.

According to one embodiment of the present invention, the at least one first metallic interconnect includes a first metallic layer, a second metallic layer arranged on the first metallic layer; and a third metallic layer arranged on the second metallic layer.

According to one embodiment of the present invention, the first metallic layer includes a copper material or a solder material.

According to one embodiment of the present invention, the second metallic layer includes a tin material or a solder material.

According to one embodiment of the present invention, the third metallic layer includes a copper material.

According to one embodiment of the present invention, the first metallic layer is in contact with the first substrate.

According to one embodiment of the present invention, the third metallic layer is in contact with second substrate.

According to one embodiment of the present invention, the third substrate is positioned above and in contact with second substrate via at least one second metallic interconnect.

According to one embodiment of the present invention, the at least one second metallic interconnect is the same as the at least one first metallic interconnect.

According to one embodiment of the present invention, the substrate arrangement further includes a fourth substrate positioned above the third substrate, the fourth substrate comprising a third through hole.

According to one embodiment of the present invention, the fourth substrate is positioned above and in contact with the third substrate via at least one third metallic interconnect.

According to one embodiment of the present invention, the at least one first metallic interconnect, the at least one second metallic interconnect and the at least one third metallic interconnect are the same.

According to one embodiment of the present invention, the second electrically conductive interconnect pillar is positioned on the second substrate and extending from the second substrate through the second through hole to electrically contact the fourth substrate.

According to one embodiment of the present invention, the substrate arrangement further includes a fifth substrate positioned above the fourth substrate.

According to one embodiment of the present invention, the fifth substrate is positioned above and in contact with the fourth substrate via at least one fourth metallic interconnect.

According to one embodiment of the present invention, the at least one fourth metallic interconnect includes a solder material.

According to one embodiment of the present invention, the substrate arrangement further includes a third electrically conductive interconnect pillar positioned on the third substrate and extending from the third substrate through the third through hole to electrically contact the fifth substrate.

According to one embodiment of the present invention, the first electrically conductive interconnect pillar is arranged in contact with the third substrate via a fifth metallic interconnect.

According to one embodiment of the present invention, the second electrically conductive interconnect pillar is arranged in contact with the fourth substrate via a sixth metallic interconnect.

According to one embodiment of the present invention, the fifth metallic interconnect is the same as the sixth metallic interconnect.

According to one embodiment of the present invention, the fifth metallic interconnect includes a fourth metallic layer and a fifth metallic layer.

According to one embodiment of the present invention, the fourth metallic layer is in contact with the first electrically conductive interconnect pillar.

According to one embodiment of the present invention, the fifth metallic layer is in contact with the third substrate.

According to one embodiment of the present invention, the fourth metallic layer includes a tin material or a solder material.

According to one embodiment of the present invention, the fifth metallic layer includes a copper material.

According to one embodiment of the present invention, the fifth metallic layer is in contact with the at least one second metallic interconnect via a first metallic connection

According to one embodiment of the present invention, the second electrically conductive interconnect pillar is in contact with the at least second metallic interconnect via a second metallic connection.

According to one embodiment of the present invention, the first metallic connection includes a copper material.

According to one embodiment of the present invention, the second metallic connection includes a copper material.

According to one embodiment of the present invention, the first electrically conductive interconnect pillar includes a copper material or a solder material.

According to one embodiment of the present invention, the first electrically conductive interconnect pillar, the second electrically interconnect pillar and the third electrically conductive interconnect pillar are the same.

According to one embodiment of the present invention, the first substrate is a semiconductor substrate with an electrical circuit formed therein.

According to one embodiment of the present invention, the first substrate, the second substrate, the third substrate and the fourth substrate are the same.

According to one embodiment of the present invention, the fifth substrate is a semiconductor substrate.

According to one embodiment of the present invention, the first through hole and the second through hole are aligned along a different axis perpendicular to a plane of the first substrate.

According to one embodiment of the present invention, the second through hole and the third through hole are aligned along a different axis perpendicular to a plane of the first substrate.

According to one embodiment of the present invention, the first substrate, the second substrate, the third substrate, the fourth substrate and the fifth substrates are arranged parallel to each other.

According to one embodiment of the present invention, the third electrically conductive interconnect pillar is arranged in contact with the fifth substrate via a seventh metallic interconnect.

According to one embodiment of the present invention, the seventh metallic interconnect is the same as the fourth metallic interconnect.

According to one embodiment of the present invention, forming the second substrate above the first substrate includes forming the second substrate such that the second substrate is in contact with the first substrate via at least one first metallic interconnect

According to one embodiment of the present invention, the at least one first metallic interconnect includes a solder material.

According to one embodiment of the present invention, the at least one first metallic interconnect includes a first metallic layer, a second metallic layer arranged on the first metallic layer; and a third metallic layer arranged on the second metallic layer.

According to one embodiment of the present invention, the first metallic layer includes a copper material or a solder material.

According to one embodiment of the present invention, the second metallic layer includes a tin material or a solder material.

According to one embodiment of the present invention, the third metallic layer includes a copper material.

According to one embodiment of the present invention, the first metallic layer is in contact with the first substrate.

According to one embodiment of the present invention, the third metallic layer is in contact with second substrate.

According to one embodiment of the present invention, forming the third substrate above the second substrate includes forming the third substrate such that the third substrate is in contact with second substrate via at least one second metallic interconnect.

According to one embodiment of the present invention, the at least one second metallic interconnect is the same as the at least one first metallic interconnect.

According to one embodiment of the present invention, the method includes forming a fourth substrate above the third substrate and forming a third through hole through the fourth substrate.

According to one embodiment of the present invention, forming the fourth substrate above the third substrate includes forming the fourth substrate such that the fourth substrate is in contact with the third substrate via at least one third metallic interconnect.

According to one embodiment of the present invention, the at least one first metallic interconnect, the at least one second metallic interconnect and the at least one third metallic interconnect are the same.

According to one embodiment of the present invention, forming the second electrically conductive interconnect pillar includes forming the second electrically conductive interconnect pillar such that the second electrically conductive interconnect pillar is positioned on the second substrate and extending from the second substrate through the second through hole to electrically contact the fourth substrate.

According to one embodiment of the present invention, the method includes forming a fifth substrate above the fourth substrate.

According to one embodiment of the present invention, forming the fifth substrate above the fourth substrate includes forming the fifth substrate such that the fifth substrate is in contact with the fourth substrate via at least one fourth metallic interconnect.

According to one embodiment of the present invention, the at least one fourth metallic interconnect includes a solder material.

According to one embodiment of the present invention, the method further includes forming a third electrically conductive interconnect pillar on the third substrate and extending from the third substrate through the third through hole to electrically contact the fifth substrate.

According to one embodiment of the present invention, forming the first electrically conductive interconnect pillar includes forming the first electrically conductive interconnect pillar such that the first electrically conductive interconnect pillar is arranged in contact with the third substrate via a fifth metallic interconnect.

According to one embodiment of the present invention, forming the second electrically conductive interconnect pillar includes forming the second electrically conductive interconnect pillar such that the second electrically conductive interconnect pillar is arranged in contact with the fourth substrate via a sixth metallic interconnect.

According to one embodiment of the present invention, the fifth metallic interconnect is the same as the sixth metallic interconnect.

According to one embodiment of the present invention, the fifth metallic interconnect includes a fourth metallic layer and a fifth metallic layer.

According to one embodiment of the present invention, the fourth metallic layer is in contact with the first electrically conductive interconnect pillar.

According to one embodiment of the present invention, the fifth metallic layer is in contact with the third substrate.

According to one embodiment of the present invention, the fourth metallic layer includes a tin material or a solder material.

According to one embodiment of the present invention, the fifth metallic layer includes a copper material.

According to one embodiment of the present invention, the method further includes forming the fifth metallic layer to be in contact with the at least one second metallic interconnect via a first metallic connection

According to one embodiment of the present invention, the method further includes forming the second electrically conductive interconnect pillar to be in contact with the at least second metallic interconnect via a second metallic connection.

According to one embodiment of the present invention, the first metallic connection includes a copper material.

According to one embodiment of the present invention, the second metallic connection includes a copper material.

According to one embodiment of the present invention, the first electrically conductive interconnect pillar includes a copper material or a solder material.

According to one embodiment of the present invention, the first electrically conductive interconnect pillar, the second electrically interconnect pillar and the third electrically conductive interconnect pillar are the same.

According to one embodiment of the present invention, the first substrate is a semiconductor substrate with an electrical circuit formed therein.

According to one embodiment of the present invention, the first substrate, the second substrate, the third substrate and the fourth substrate are the same.

According to one embodiment of the present invention, the fifth substrate is a semiconductor substrate.

According to one embodiment of the present invention, forming the first through hole and the second through hole includes forming the first through hole and the second through hole such that the first through hole and the second through hole are aligned along a different axis perpendicular to a plane of the first substrate.

According to one embodiment of the present invention, forming the second through hole and the third through hole includes forming the second through hole and the third through hole such that the second through hole and the third through hole are aligned along a different axis perpendicular to a plane of the first substrate.

According to one embodiment of the present invention, the first substrate, the second substrate, the third substrate, the fourth substrate and the fifth substrates are arranged parallel to each other.

According to one embodiment of the present invention, the method further includes forming the third electrically conductive interconnect pillar to be in contact with the fifth substrate via a seventh metallic interconnect.

According to one embodiment of the present invention, the seventh metallic interconnect is the same as the fourth metallic interconnect.

According to one embodiment of the present invention, the chip further includes a first metallic interconnect positioned on the first surface of the substrate, adjacent to the electrically conductive interconnect pillar.

According to one embodiment of the present invention, the chip further includes a first metallic interconnect positioned on a second surface of the substrate.

According to one embodiment of the present invention, the first surface of the substrate is arranged opposite to the second surface of the substrate.

According to one embodiment of the present invention, the through hole extends through the first surface of the substrate to the second surface of the substrate.

According to one embodiment of the present invention, the through hole is positioned adjacent to the electrically conductive interconnect pillar and the first metallic interconnect.

According to one embodiment of the present invention, the chip further includes a second metallic interconnect positioned on the electrically conductive interconnect pillar.

According to one embodiment of the present invention, the substrate is a semiconductor substrate.

According to one embodiment of the present invention, the electrically conductive interconnect pillar extends from the first surface of the substrate in a direction at least substantially perpendicular thereto in a tapered manner.

According to one embodiment of the present invention, the electrically conductive interconnect pillar includes a copper material or a solder material.

According to one embodiment of the present invention, the first metallic interconnect includes a solder material.

According to one embodiment of the present invention, the first metallic interconnect includes a first metallic layer, a second metallic layer arranged on the first metallic layer; and a third metallic layer arranged on the second metallic layer.

According to one embodiment of the present invention, the first metallic layer includes a copper material.

According to one embodiment of the present invention, the second metallic layer includes a tin material or a solder material.

According to one embodiment of the present invention, the third metallic layer includes a copper material or a solder material.

According to one embodiment of the present invention, the second metallic interconnect includes a solder material.

According to one embodiment of the present invention, the second metallic interconnect includes fourth metallic layer and a fifth metallic layer.

According to one embodiment of the present invention, the fourth metallic layer includes a tin material or a solder material.

According to one embodiment of the present invention, the fifth metallic layer includes a copper material.

According to one embodiment of the present invention, the method further includes forming a first metallic interconnect on the first surface of the substrate, the first metallic interconnect being positioned adjacent to the electrically conductive interconnect pillar.

According to one embodiment of the present invention, the method further includes forming a first metallic interconnect on a second surface of the substrate

According to one embodiment of the present invention, the first surface of the substrate is arranged opposite to the second surface of the substrate.

According to one embodiment of the present invention, forming the through hole through the substrate includes forming the through hole through the first surface of the substrate through to the second surface of the substrate.

According to one embodiment of the present invention, the method further includes forming the through hole such that the through hole is positioned adjacent to the electrically conductive interconnect pillar and the first metallic interconnect.

According to one embodiment of the present invention, the method further includes forming a second metallic interconnect on the electrically conductive interconnect pillar.

According to one embodiment of the present invention, the substrate is a semiconductor substrate.

According to one embodiment of the present invention, forming the electrically conductive interconnect pillar includes forming the electrically conductive interconnect pillar such that the electrically conductive interconnect pillar extends from the first surface of the substrate in a direction at least substantially perpendicular thereto in a tapered manner.

According to one embodiment of the present invention, the electrically conductive interconnect pillar includes a copper material or a solder material.

According to one embodiment of the present invention, the first metallic interconnect includes a solder material.

According to one embodiment of the present invention, the first metallic interconnect includes a first metallic layer, a second metallic layer arranged on the first metallic layer; and a third metallic layer arranged on the second metallic layer.

According to one embodiment of the present invention, the first metallic layer includes a copper material.

According to one embodiment of the present invention, the second metallic layer includes a tin material or a solder material.

According to one embodiment of the present invention, the third metallic layer includes a copper material or a solder material.

According to one embodiment of the present invention, the second metallic interconnect includes a solder material.

According to one embodiment of the present invention, the second metallic interconnect includes fourth metallic layer and a fifth metallic layer.

According to one embodiment of the present invention, the fourth metallic layer includes a tin material or a solder material.

According to one embodiment of the present invention, the fifth metallic layer includes a copper material.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A substrate arrangement comprising:
a first substrate;
a second substrate positioned above the first substrate, the second substrate comprising a first through hole;
a third substrate positioned above the second substrate, the third substrate comprising a second through hole;
a first electrically conductive interconnect pillar positioned on the first substrate and extending from the first substrate through the first through hole to electrically contact the third substrate; and
a second electrically conductive interconnect pillar positioned on the second substrate and extending from the second substrate through the second through hole.

2. The substrate arrangement of claim 1, wherein the second substrate is positioned above and in contact with the first substrate via at least one first metallic interconnect.

3. (canceled)

4. The substrate arrangement of claim 2, wherein the at least one first metallic interconnect includes
a first metallic layer,
a second metallic layer arranged on the first metallic layer; and
a third metallic layer arranged on the second metallic layer.

5-7. (canceled)

8. The substrate arrangement of claim 4, wherein the first metallic layer is in contact with the first substrate.

9. The substrate arrangement of claim 4, wherein the third metallic layer is in contact with second substrate.

10. The substrate arrangement of claim 1, wherein the third substrate is positioned above and in contact with second substrate via at least one second metallic interconnect.

11. (canceled)

12. The substrate arrangement of claim 1, further comprising a fourth substrate positioned above the third substrate, the fourth substrate comprising a third through hole.

13. The substrate arrangement of claim 12, wherein the fourth substrate is positioned above and in contact with the third substrate via at least one third metallic interconnect.

14-36. (canceled)

37. The substrate arrangement of claim 1, wherein the first through hole and the second through hole are aligned along a different axis perpendicular to a plane of the first substrate.

38. The substrate arrangement of claim 12, wherein the second through hole and the third through hole are aligned along a different axis perpendicular to a plane of the first substrate.

39-41. (canceled)

42. A method of manufacturing a substrate arrangement comprising:
forming a second substrate above a first substrate;
forming a first through hole through the second substrate;
forming a third substrate above the second substrate;
forming a second through hole through the third substrate;
forming a first electrically conductive interconnect pillar on the first substrate, the first electrically conductive interconnect pillar extending from the first substrate through the first through hole to electrically contact the third substrate; and
forming a second electrically conductive interconnect pillar on the second substrate, the second electrically conductive interconnect pillar extending from the second substrate through the second through hole.

43-83. (canceled)

84. A chip comprising:
a substrate having an electrical circuit formed therein;
an electrically conductive interconnect pillar positioned on a first surface of the substrate and extending from the first surface of the substrate; and
a through hole formed through the substrate, wherein the through hole is formed in such a dimension that an electrically conductive interconnect pillar of another substrate of the same dimension as the electrically conductive interconnect pillar can be received in the through hole and
wherein the through hole is spaced apart from the electrically conductive interconnect pillar with respect to a horizontal direction.

85. The chip of claim 84, further comprising a first metallic interconnect positioned on the first surface of the substrate, adjacent to the electrically conductive interconnect pillar.

86. The chip of claim 84, further comprising a first metallic interconnect positioned on a second surface of the substrate.

87. The chip of claim 86, wherein the first surface of the substrate is arranged opposite to the second surface of the substrate.

88. The chip of claim 87, wherein the through hole extends through the first surface of the substrate to the second surface of the substrate.

89. The chip of claim 84, wherein the through hole is positioned adjacent to the electrically conductive interconnect pillar and the first metallic interconnect.

90. The chip of claim 84, further comprising a second metallic interconnect positioned on the electrically conductive interconnect pillar.

91. (canceled)

92. The chip claim 84, wherein the electrically conductive interconnect pillar extends from the first surface of the substrate in a direction at least substantially perpendicular thereto in a tapered manner.

93-102. (canceled)

103. A method of manufacturing a chip, the method comprising:
forming an electrical circuit in a substrate;
forming an electrically conductive interconnect pillar on a first surface of the substrate, the electrically conductive interconnect pillar extending from the first surface of the substrate;
forming a through hole through the substrate, wherein the through hole is formed in such a dimension that an electrically conductive interconnect pillar of another substrate of the same dimension as the electrically conductive interconnect pillar can be received in the through hole and
wherein the through hole is spaced apart from the electrically conductive interconnect pillar with respect to a horizontal direction.

104-121. (canceled)
